(19) United States
(12) Patent Application Publication
(10) Pub. No.: US 2007/0145356 A1
(43) Pub. Date: Jun. 28, 2007

(54) Carbon nanotube interdigitated sensor

(76) Inventors: Islamshah S. Amlani, Chandler, AZ (US); George N. Maracas, Phoenix, AZ (US); Larry A. Nagahara, Phoenix, AZ (US)

Correspondence Address: INGRASSIA FISHER & LORENZ, P.C., 7150 E. CAMELBACK, STE. 325, SCOTTSDALE, AZ, 85251, US

(21) Appl. No.: 11/316,718

(22) Filed: Dec. 22, 2005

(51) Int. Cl. H01L 29/08

(52) U.S. Cl. 257/40

(57) ABSTRACT

A carbon nanotube sensor (30), for determining the degree of the presence of an unwanted environmental agent, includes a plurality of carbon nanotubes (18). The sensor (30) comprises first and second conducting layers (32, 34) having alternatively interdigitated fingers (36, 38). The plurality of carbon nanotubes (18) having a material characteristic are coupled between each of the interdigitated fingers (36, 38). Optionally, a gate may be used for biasing the device for specific sensor applications by adjusting the electrical resistance.

### FIELD OF THE INVENTION

The present invention generally relates to carbon nanotube sensors, and more particularly to a carbon nanotube sensor including a plurality of carbon nanotubes.

### BACKGROUND OF THE INVENTION

One-dimensional nanostructures, such as belts, rods, tubes and wires, have become the latest focus of intensive research with their own unique applications. One-dimensional nanostructures are model systems to investigate the dependence of electrical and thermal transport or mechanical properties as a function of size reduction. In contrast with zero-dimensional, e.g., quantum dots, and two-dimensional nanostructures, e.g., GaAs/AlGaAs superlattice, direct synthesis and growth of one-dimensional nanostructures has been relatively slow due to difficulties associated with controlling the chemical composition, dimensions, and morphology. Alternatively, various one-dimensional nanostructures have been fabricated using a number of advanced nanolithographic techniques, such as electron-beam (e-beam), focused-ion-beam (FIB) writing, and scanning probe.

Carbon nanotubes are one of the most important species of one-dimensional nanostructures. Carbon nanotubes are one of four unique crystalline structures for carbon, the other three being diamond, graphite, and fullerene. In particular, carbon nanotubes refer to a helical tubular structure grown with a single wall (single walled nanotubes) or multiple wall (multi-walled nanotubes). These types of structures are obtained by rolling a sheet formed of a plurality of hexagons. The sheet is formed by combining each carbon atom thereof with three neighboring carbon atoms to form a helical tube. Carbon nanotubes typically have a diameter in the order of a fraction of a nanometer to a few hundred nanometers. As used herein, a “carbon nanotube” is any fullerene-related structure which consists of graphene cylinders closed at either end with caps containing pentagonal rings or without caps at the ends.

Carbon nanotubes can function as either a conductor, like metal, or a semiconductor, according to the rolled shape and the diameter of the helical tubes. With metallic-like nanotubes, a one-dimensional carbon-based structure can conduct a current at room temperature with essentially no resistance. Further, electrons can be considered as moving freely through the structure, so that metallic-like nanotubes can be used as ideal electrical interconnects. When semiconductor nanotubes are connected to two metal electrodes, the structure can function as a field effect transistor wherein the nanotubes can be switched from a conducting to an insulating state by applying a voltage to a gate electrode. Therefore, carbon nanotubes are potential building blocks for nanoelectronic and sensor devices because of their unique structural, physical, and chemical properties.

Another class of one-dimensional nanostructures is nanowires. Nanowires of inorganic materials have been grown from metal (Ag, Au), elemental semiconductors (e.g., Si, and Ge), III-V semiconductors (e.g., GaAs, GaN, GaP, InAs, and InP), II-VI semiconductors (e.g., CdS, CdSe, ZnS, and ZnSe) and oxides (e.g., SiO₂ and ZnO). Similar to carbon nanotubes, inorganic nanowires can be synthesized with various diameters and length, depending on the synthesis technique and/or desired application needs.

Both carbon nanotubes and inorganic nanowires have been demonstrated as field effect transistors (FETs) and other basic components in nanoscale electronic such as p-n junctions, bipolar junction transistors, inverters, etc. The motivation behind the development of such nanoscale components is that “bottom-up” approach to nanoelectronics has the potential to go beyond the limits of the traditional “top-down” manufacturing techniques.

A major application for one-dimensional nanostructures is chemical and biological sensing. The extremely high surface-to-volume ratios associated with these nanostructures make their electrical properties extremely sensitive to species adsorbed on their surface. For example, the surfaces of semiconductor nanowires have been modified and implemented as highly sensitive, real-time sensors for pH and biological species.

Single walled carbon nanotubes have been shown to be a highly sensitive chemical and biological sensor. The utility of detecting the presence or absence of a specific agent is one type of known detection scheme. As the agent attaches itself to a nanotube, the measurable resistance of the nanotube changes. As the resistance changes, a quantitative result, e.g., concentration, may be determined. Known nanotube systems use a single nanotube (only one path for determining resistance), a random network, or an array of nanotubes to determine the presence of an unwanted agent.

Since the size and chirality of carbon nanotubes are not completely controllable by known growth techniques, it is difficult to predict the electrical properties in such a device.

Accordingly, it is desirable to provide a carbon nanotube sensor with little or no device-to-device variation. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A carbon nanotube sensor, for determining the degree of the presence of an unwanted environmental agent, includes a plurality of carbon nanotubes. The sensor comprises first and second conducting layers having alternatively interdigitated fingers. The plurality of carbon nanotubes having a material characteristic are coupled between each of the interdigitated fingers. Optionally, a gate may be used for biasing the device for specific sensor applications by adjusting the electrical resistance.

### BRIEF DESCRIPTION OF THE DRAWINGS

The present invention will hereinafter be described in conjunction with the following drawing figures, wherein like numerals denote like elements, and

FIGS. 1 and 2 are partial perspective views of an exemplary embodiment of the present invention in progressive states of fabrication;

FIG. 3 is a partial cross section of the exemplary embodiment of FIG. 2;

FIG. 4 is a partial top view of the exemplary embodiment;

FIG. 5 is a graph showing the distribution of a single carbon nanotube device conductance;

FIG. 6 is a graph showing the distribution of a plurality of devices, each having a plurality of carbon nanotubes; and

FIG. 7 is a block diagram of a circuit for measuring characteristics of the exemplary embodiment.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

When a molecule attaches itself to a nanostructure, such as a carbon nanotube, a characteristic of the material changes, such as the change in a current flowing in the nanotube that is measurable in a manner known to those skilled in the art. While a carbon nanotube is the preferred embodiment of the nanostructure, other embodiments would include, and for the purposes of this patent be included within the definition of carbon nanotubes, all other nanostructures with a high aspect ratio (length versus width), for example, carbon fibers, nanowires, and nanoribbons. Additionally, the nano-structure may be coated with a substance for determining specific environmental agents. And while a change in current is the preferred embodiment for the measurable material characteristic, other embodiments would include, for example, magnetic, optical, frequency, and mechanical.

By measuring this change in the current, it is known that a determination may be made as to the number of molecules that have attached to the carbon nanotube, and therefore, a correlation to the concentration of the molecules in the environment around the carbon nanotube. Known systems place an electrode across a carbon nanotube to measure this change in the material characteristic.

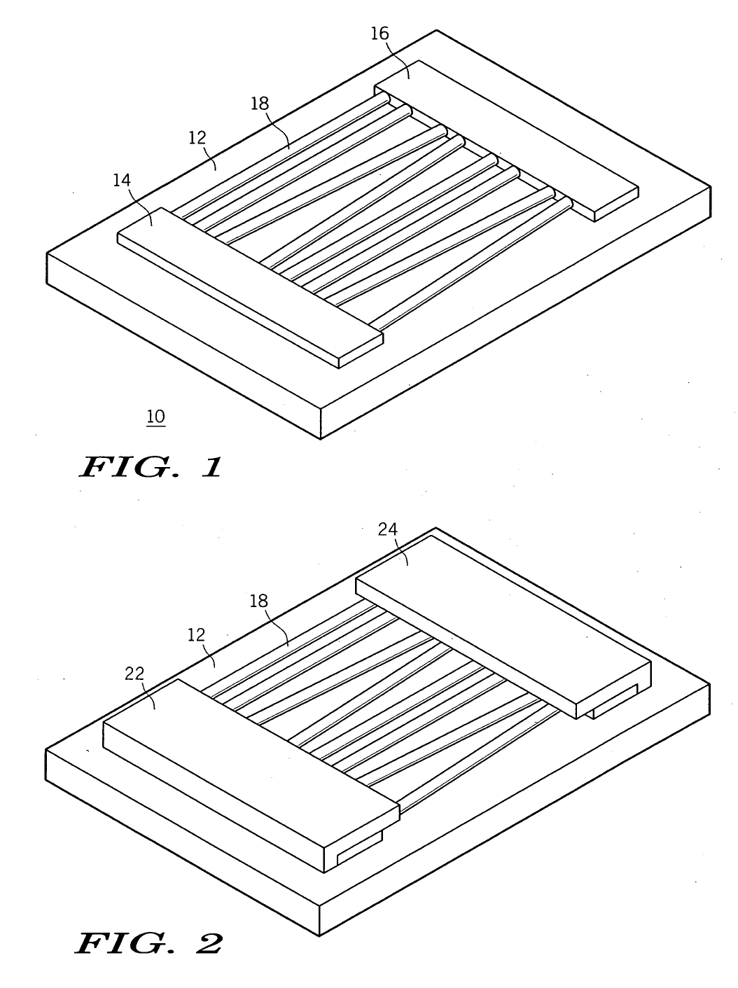

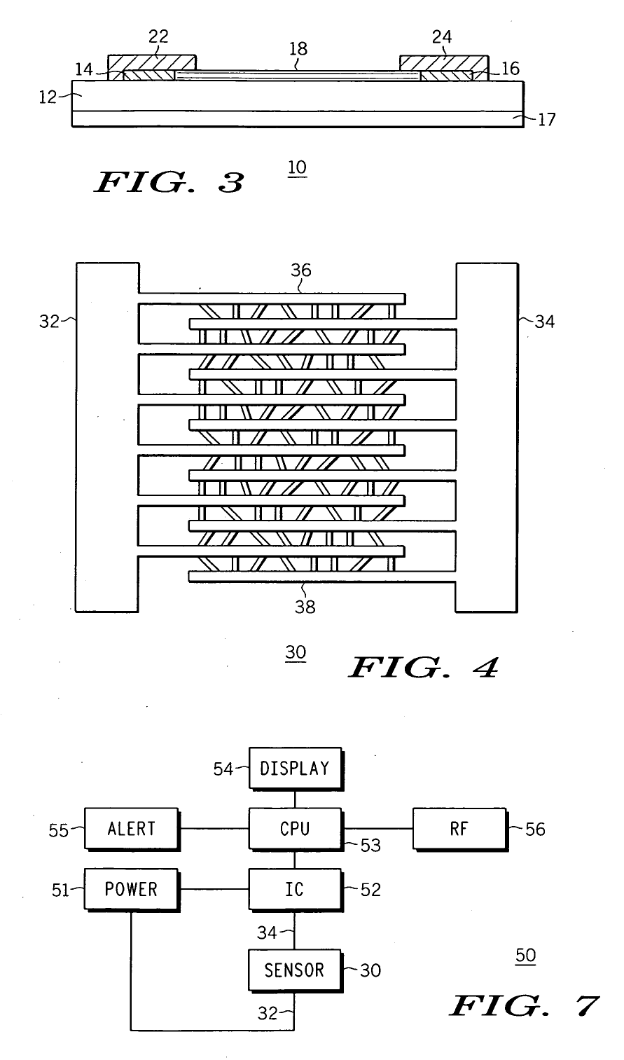

Referring to FIG. 1, the structure 10 includes catalysts 14 and 16 positioned on the substrate 12. Carbon nanotubes 18, which may be single walled or multi-walled, are grown from each of the catalysts 14 and 16 and may extend in any direction, though for simplicity of illustration, only those growing generally in opposed directions are shown. The carbon nanotubes 18 grow from both catalysts 14 and 16 and do not necessarily reach the other catalyst 14 or 16. The carbon nanotubes 18 are positioned on the substrate 12 as shown, but alternatively some or all may be positioned above the substrate 12. Electrodes 22 and 24 (FIGS. 2 and 3) are then formed above the catalysts 14 and 16, respectively, making electrical contact with the carbon nanotubes 18. Lithographic masking and etching techniques are then used to remove the carbon nanotubes 18 not connected between the electrodes 22 and 24. Although some carbon nanotubes 18 may touch, even cross, other carbon nanotubes 18, each carbon nanotube 18 will extend from electrode 22 to electrode 24.

The substrate 12 comprises preferably silicon dioxide; however, alternate materials, for example, glass, ceramic, metal, a semiconductor material, or a flexible material are anticipated by this disclosure. Substrate 12 can include control electronics or other circuitry, some of which may comprise circuitry shown in FIG. 7 (discussed later). Also, substrate 12 may include an insulating layer, such as silicon dioxide, silicon nitride, or the like. The catalysts 14 and 16 are deposited onto the substrate, preferably at room temperature, resulting in a thin layer of approximately 10 angstroms to 100 angstroms. The catalysts 14 and 16 preferably comprise Nickel (Ni), but alternatively can be formed of other metals, or alloys made of transition metal, for example, iron/cobalt (Fe/Co), nickel/cobalt (Ni/Co), or iron/nickel (Fe/Ni). A carbon vapor deposition growth using hydrogen (H₂) and a carbon containing gas, for example methane (CH₄), is accomplished at between 450° C. and 1000° C., but preferably at 850° C. for single walled growth or 500° C. for multi-walled growth. This growth results in the metal catalyst 14 and 16 including particles (not shown) within the thin layers of catalysts 14 and 16. Simultaneously, as the particles are being formed, carbon nanotubes 18 grow on these particles. The material used for the catalyst 14 and 16 allows for both the direct and selective growth of carbon nanotubes 18 by CVD techniques, e.g., thermal CVD, HF-CVD, and PE-CVD, at low temperature and a controlled electron transport and injection in the carbon nanotubes 18 modulated by an applied voltage.

Referring to FIGS. 2 and 3, electrodes 22 and 24 are formed generally over catalysts 14 and 16, wherein the carbon nanotubes 18 make electrical contact therebetween. The electrodes 22 and 24 comprise Ti/Au, but may comprise any conducting material. The electrodes 22 and 24 are preferably spaced between 10 nanometers and 1 millimeters apart. The thickness of the electrodes 14, 16 is generally between 0.01 and 100 micrometers, and would preferably be 1.0 micrometer.

Optionally, a gate 17 is positioned on the substrate 12 for biasing the device for specific sensor applications by adjusting the electrical resistance.

However, since a single carbon nanotube 18 may suffer from device-to-device variation, which limits the usability of the device for sensing applications, a plurality of carbon nanotubes 18 are positioned across the pair of electrodes 22 and 24 to minimize these issues.

Although only one method of nanotube growth is disclosed above, the nanotubes 18 may be grown, or previously grown and placed in place, in any manner known to those skilled in the art, and are typically 10 nm to 1 cm in length and less than 1 nm to 100 nm in diameter. Contact between the nanotubes 18 and electrodes 22 and 24 is made during fabrication, for example, by any type of lithography, e-beam, optical, soft lithography, or imprint technology.

Referring to FIG. 4, an exemplary embodiment of the present invention comprises a device 30 including a first electrode 32 and a second electrode 34. The first electrode 32 includes a first plurality of fingers 36 and the second electrode 34 includes a second plurality of fingers 38. Each adjacent first and second plurality of fingers 36 and 38 are coupled individually by a plurality of carbon nanotubes 18.

While six fingers 36 and six fingers 38 are shown in FIG. 4, it should be understood that any number of fingers could be used. Additionally, while only a few carbon nanotubes 18 are shown between each of the fingers 36 and 38, preferably many thousands of the carbon nanotubes 18 would electrically connect each of the adjacent fingers 36 and 38.

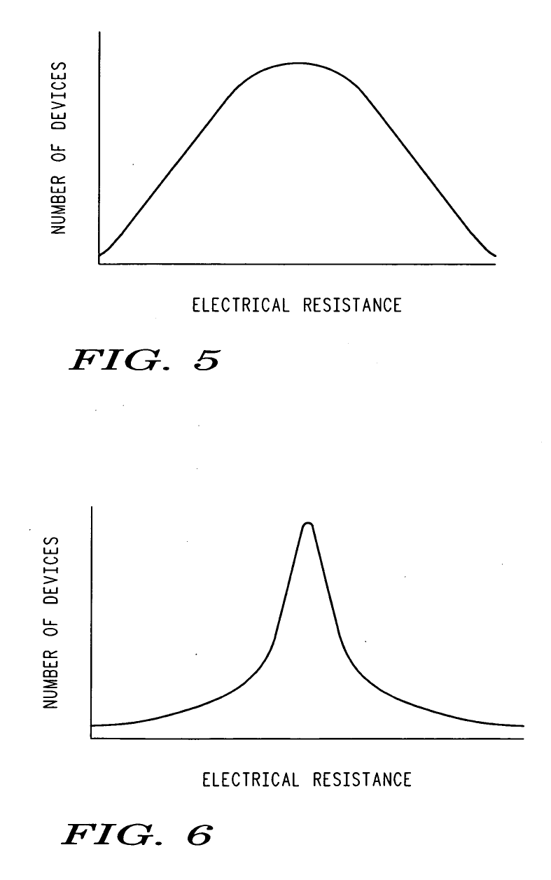

The graph of FIG. 5 shows the distribution of electrical resistance of a plurality of devices having a single carbon nanotube. In comparison, the graph of FIG. 6 shows the distribution of electrical resistance of a plurality of devices having a plurality of carbon nanotubes. The electrical resistance of a device with a plurality of carbon nanotubes represents a statistical average of individual nanotubes. The variation shown in FIG. 6 for a plurality of devices having a plurality of carbon nanotubes has a tighter distribution than that shown in FIG. 5 for a plurality of devices having a single carbon nanotube.

Furthermore, the use of a varying number of interdigitated fingers gives the ability to better determine the concentration range of the environmental agent. The dynamic range of the detector may be varied by varying the number of fingers and the density of carbon nanotubes between the fingers. The dynamic range of a detector is that concentration range over which a concentration dependent output is produced. The minimum of the range will be the concentration at which the output is equivalent to twice the noise level and the maximum of the range will be the concentration where the detector no longer responds to a concentration increase. The effective sensor volume increases with number of nanotubes in the detector. Higher volume can produce higher dynamic range as the sensor can adsorb more gas molecules before saturating its available binding sites.

The carbon nanotubes may be either chemically functionalized or coated to provide better selectivity and/or sensitivity to a particular environmental agent.

The sensor described herein provides a large number of carbon nanotubes 18 such that the average is predictable, thereby eliminating the need to make shorter nanotubes identical in diameter and chirality.

Referring to FIG. 7, an exemplary system 50 includes the device 30, for example, having its electrodes 32 and 34 coupled to a power source 51, e.g., a battery. A circuit 52 determines the current between the electrodes and supplies the information to a processor 53. The information may be transferred from the processor 53 to a display 54, an alert device 55, or an RF transmitter 56.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. A device comprising:
first and second conducting layers having alternatively interdigitated fingers; and
a plurality of carbon nanotubes having a material characteristic, each of the carbon nanotubes extending betweenat least two of the interdigitated fingers.

2. The device of claim 1 wherein the material characteristic is an electrical resistance from the first conducting layer through the carbon nanotube to the second conducting layer.

3. The device of claim 1 wherein the material characteristic comprises one of electrical, magnetic, optical, frequency, and mechanical.

4. The device of claim 1 further comprising circuitry coupled to the first and second conducting layers for determining a measurable change in the material characteristic of at least some of the plurality of carbon nanotubes.

5. The device of claim 1 wherein the carbon nanotubes comprise chemically functionalized carbon nanotubes.

6. The device of claim 1 further comprising a gate contiguous to the plurality of carbon nanotubes to bias the device for a specific sensor application.

7. The device of claim 1 wherein the interdigitated fingers are spaced between 10 nanometers and 1 millimeter apart.

8. A device comprising:
a first conducting material having first and second fingers;
a second conducting material having a third finger positioned between the first and second fingers;
a first plurality of carbon nanotubes positioned between the first and third fingers;
a second plurality of carbon nanotubes positioned between the second and third fingers; and
circuitry coupled to the first and second conducting material for determining a measurable change in the material characteristic in at least one of the first and second sections.

9. The device of claim 8 wherein the material characteristic is an electrical resistance from the first conducting material through the first and second plurality of carbon nanotubes to the second conducting material.

10. The device of claim 8 wherein the material characteristic comprises one of electrical, magnetic, optical, frequency, and mechanical.

11. The device of claim 8 wherein the carbon nanotubes comprise chemically functionalized carbon nanotubes.

12. The device of claim 8 further comprising a gate contiguous to the plurality of carbon nanotubes to bias the device for a specific sensor application.

13. The device of claim 8 wherein the first, second, and third fingers are spaced between 10 nanometers and 1 millimeters from an adjacent first, second, and third finger.

14. A device comprising:
a first conducting material having a first plurality of fingers;
a second conducting material having a second plurality of fingers, each alternatively positioned between two of the first plurality of fingers;
a plurality of carbon nanotubes positioned between each of the alternating first and second plurality of fingers; and
circuitry coupled to the first and second conducting material for measuring a change of a material characteristic of the carbon nanotubes when exposed to an environmental agent.

15. The device of claim 14 wherein the material characteristic is an electrical resistance from the first conducting layer through the plurality of carbon nanotubes to the second conducting layer.

16. The device of claim 14 wherein the material characteristic comprises one of electrical, magnetic, optical, frequency, and mechanical.

17. The device of claim 14 wherein the carbon nanotubes comprise chemically functionalized carbon nanotubes.

18. The device of claim 14 further comprising a gate contiguous to the plurality of carbon nanotubes to bias the device for a specific sensor application.

19. The device of claim 14 wherein each of the fingers are spaced between 10 nanometers and 1 millimeter from one another.
